(19) United States
(12) Patent Application Publication
(10) Pub. No.: US 2020/0183606 A1
(43) Pub. Date: Jun. 11, 2020

(54) Wear-Leveling Scheme and Implementation for a Storage Class Memory System

(71) Applicant: Huawei Technologies Co., Ltd., Shenzhen (CN)

(72) Inventor: Chaohong Hu, San Jose, CA (US)

(21) Appl. No.: 16/785,967

(22) Filed: Feb. 10, 2020

Related U.S. Application Data
(63) Continuation of application No. PCT/US2018/063106, filed on Nov. 29, 2018.

(51) Int. Cl. G06F 3/06; G11C 16/10

(52) U.S. Cl. CPC G06F 3/0644; G11C 16/10; G06F 3/0616

(57) ABSTRACT

A method of performing wear-leveling on a memory implemented by a memory system, comprises determining, by a processor coupled to the receiver and the memory, a circular shifter offset based on a write count of the first portion of the memory, and writing, by the memory, the plurality of user bits and the plurality of error-correcting code (ECC) bits to a plurality of memory cells within a first portion of the memory and a second portion of the memory based on the circular shifter offset.

### CROSS-REFERENCE TO RELATED APPLICATIONS

This application is a continuation of International Patent Application No. PCT/US2018/063106 filed on Nov. 29, 2018, and entitled “A Wear-Leveling Scheme and Implementation for a Storage Class Memory System” which claims priority to U.S. Provisional Patent Application No. 62/597,758 filed Dec. 12, 2017 by Chaohong Hu, and entitled “A Wear-Leveling Scheme and Implementation for a Storage Class Memory System,” which is incorporated herein by reference as if reproduced in their entirety.

### FIELD OF INVENTION

The present disclosure pertains to the field of memory management. In particular, the present disclosure relates to increasing a lifespan of memory cells within a memory system.

### BACKGROUND

The wear on memory cells, or physical locations, within a memory system varies depending upon how often each of the cells is programmed. If a memory cell is programmed once and then effectively never reprogrammed, the wear associated with that cell will generally be relatively low. However, if a memory cell is repetitively written to and erased, the wear associated with that cell will generally be relatively high. In data storage systems, the same physical locations of memory cells are repeatedly written to and erased if a host repeatedly uses the same physical address to write and overwrite data.

### SUMMARY

According to a first aspect of the present disclosure, there is provided a method implemented by a memory system. The method comprises receiving, by a receiver coupled to the memory, a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits, determining, by a processor coupled to the receiver and the memory, a circular shifter offset based on a write count of the first portion of the memory, and writing, by the memory, the plurality of user bits and the plurality of ECC bits to a plurality of memory cells within the first portion of the memory and the second portion of the memory based on the circular shifter offset.

In a first implementation of the method according to the first aspect, the circular shifter offset is an integer value corresponding to a number of memory cells by which to shift the plurality of user bits and the plurality of ECC bits within the first portion of the memory and the second portion of the memory, wherein the circular shifter offset equals to the write count/K, wherein K is a predefined constant associated with the write counts.

In a second implementation of the method according to the first aspect or any preceding implementation of the first aspect, the write count comprises a plurality of write count bits, wherein the method further comprises performing, by the processor, balanced gray code (BGC) encoding on the plurality of write count bits of the write count after incrementing the write count and before writing the plurality of user bits and the plurality of ECC bits to the plurality of memory cells.

In a third implementation of the method according to the first aspect or any preceding implementation of the first aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein writing the plurality of user bits and the plurality of ECC bits to the plurality of memory cells comprises shifting a location for storing each of the plurality of user bits and the plurality of ECC bits at one of the plurality of memory cells by the circular shifter offset.

In a fourth implementation of the method according to the first aspect or any preceding implementation of the first aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein writing the plurality of user bits and the plurality of ECC bits to the plurality of memory cells comprises shifting a location for storing each of the plurality of user bits and the plurality of ECC bits at one of the plurality of memory cells by the circular shifter offset.

In a fifth implementation of the method according to the first aspect or any preceding implementation of the first aspect, the write count comprises a plurality of write count bits, and wherein the method further comprises incrementing the write count after receiving the write command.

In a sixth implementation of the method according to the first aspect or any preceding implementation of the first aspect, the method further comprises computing, by the processor, the plurality of ECC bits corresponding to the plurality of user bits.

In a seventh implementation of the method according to the first aspect or any preceding implementation of the first aspect, the memory is a storage class memory.

In an eighth implementation of the method according to the first aspect or any preceding implementation of the first aspect, the first portion and the second portion are not contiguously stored in the memory.

According to a second aspect of the present disclosure, there is provided an apparatus implemented as a memory system. The apparatus comprises a memory storage comprising instructions, and one or more processors in communication with the memory storage, wherein the one or more processors execute the instructions to receive a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits, determine a circular shifter offset based on a write count of the first portion of the memory, and write the plurality of user bits and the plurality of ECC bits to a plurality of memory cells within the first portion of the memory and the second portion of the memory based on the circular shifter offset.

In a first implementation of the apparatus according to the second aspect, the circular shifter offset is an integer value corresponding to a number of memory cells by which to shift the plurality of user bits and the plurality of ECC bits within the first portion of the memory and the second portion of the memory, wherein the circular shifter offset is equal to the write count/K, wherein K is a predefined constant associated with the write counts.

In a second implementation of the apparatus according to the second aspect or any preceding implementation of the second aspect, the write count comprises a plurality of write count bits, wherein the one or more processors execute the instructions to perform balanced gray code (BGC) encoding on the plurality of write count bits of the write count after incrementing the write count and before writing the plurality of user bits and the plurality of ECC bits to the plurality of memory cells.

In a third implementation of the apparatus according to the second aspect or any preceding implementation of the second aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein the one or more processors execute the instructions to shift a location for storing each of the plurality of user bits and the plurality of ECC bits at one of the plurality of memory cells by the circular shifter offset.

In a fourth implementation of the apparatus according to the second aspect or any preceding implementation of the second aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein the one or more processors execute the instructions to shift a location for storing each of the plurality of user bits and the plurality of ECC bits at one of the plurality of memory cells by the circular shifter offset.

In a fifth implementation of the apparatus according to the second aspect or any preceding implementation of the second aspect, the write count comprises a plurality of write count bits, and wherein the one or more processors execute the instructions to increment the write count after receiving the write command.

In a sixth implementation of the apparatus according to the second aspect or any preceding implementation of the second aspect, the one or more processors execute the instructions to compute the plurality of ECC bits corresponding to the plurality of user bits.

According to a third aspect of the present disclosure, there is provided a non-transitory medium configured to store a computer program product comprising computer executable instructions that when executed by a processor cause the processor to receive a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits, determine a circular shifter offset based on a write count of the first portion of the memory, and write the plurality of user bits and the plurality of ECC bits to a plurality of memory cells within the first portion of the memory and the second portion of the memory based on the circular shifter offset.

In a first implementation of the non-transitory medium according to the third aspect, the circular shifter offset is an integer value corresponding to a number of memory cells by which to shift the plurality of user bits and the plurality of ECC bits within the first portion of the memory and the second portion of the memory, wherein the circular shifter offset is equal to the write count/K, wherein K is a predefined constant associated with the write counts.

In a second implementation of the non-transitory medium according to the third aspect or any preceding implementation of the third aspect, the write count comprises a plurality of write count bits, wherein the computer executable instructions when executed by the processor further cause the processor to perform balanced gray code (BGC) encoding on the plurality of write count bits of the write count after incrementing the write count and before writing the plurality of user bits and the plurality of ECC bits to the plurality of memory cells.

In a third implementation of the non-transitory medium according to the third aspect or any preceding implementation of the third aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein the computer executable instructions when executed by the processor further cause the processor to shift a location for storing each of the plurality of user bits and the plurality of ECC bits at one of the plurality of memory cells by the circular shifter offset.

In a fourth implementation of the non-transitory medium according to the third aspect or any preceding implementation of the third aspect, the circular shifter offset is an integer value corresponding to the number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein the computer executable instructions when executed by the processor further cause the processor to shift a location for storing each of the plurality of user bits and the plurality of ECC bits at one of the plurality of memory cells by the circular shifter offset.

In a fifth implementation of the non-transitory medium according to the third aspect or any preceding implementation of the third aspect, the write count comprises a plurality of write count bits, and wherein the computer executable instructions when executed by the processor further cause the processor to increment the write count after receiving the write command.

In a sixth implementation of the non-transitory medium according to the third aspect or any preceding implementation of the third aspect, the computer executable instructions when executed by the processor further cause the processor to compute the plurality of ECC bits corresponding to the plurality of user bits.

Wear-leveling typically involves moving large blocks of data (thousands of bits) to different memory locations at certain time intervals. However, there is currently no mechanism for performing fine grained wear-leveling on specific bits within the large blocks of data. Current mechanisms for wear-leveling also do not take into account the corresponding ECC bits that may change more frequently that the user bits.

The wear-leveling schemes disclosed herein are advantageous in that the wear-leveling schemes disclosed herein involve changing the location of storing particular bits or nibbles of data, rather than large blocks of thousands of bits of data. This results in a more precise and accurate manner of controlling the lifespan of memory cells within a memory. In this way, the wear-leveling schemes disclosed herein increase the lifespan of a memory by increasing a lifespan of each of the memory cells within the memory.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a diagram illustrating an example of a memory system configured to perform wear-leveling according to various embodiments of the disclosure.

FIG. 2 is a diagram illustrating a relationship between physical addresses and logical addresses of memory cells in a memory according to various embodiments of the disclosure.

FIG. 3 is a diagram illustrating a difference in a write ratio between the ECC bits of a codeword and user bits of the codeword according to various embodiments of the disclosure.

FIG. 4 is a diagram illustrating a method of wear-leveling according to various embodiments of the disclosure.

FIG. 5 is a diagram illustrating an example of a method for performing wear-leveling according to various embodiments of the disclosure.

FIG. 6 is a diagram illustrating another example of a method for performing wear-leveling according to various embodiments of the disclosure.

FIG. 7 is a diagram illustrating an example of a method for performing wear-leveling on the memory cells storing the write count for a first portion of memory according to various embodiments of the disclosure.

FIG. 8 is a diagram of an embodiment of a memory system according to various embodiments of the disclosure.

FIG. 9 is a flowchart illustrating a method for performing wear-leveling on the memory according to various embodiments of the disclosure.

FIG. 10 is a diagram illustrating an apparatus for performing wear-leveling on the memory according to various embodiments of the disclosure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

User data is typically received from a user and stored as user bits. Error-correcting code (ECC) bits are computed based on the user bits and used to perform error detection and correction on the user bits. A write command comprising user bits that are to be written to a memory may be received by a memory system. The memory system may be configured to compute ECC bits for the user bits received in the write command. The user bits may be written to a first portion of the memory, and the ECC bits may be written to a second portion of the memory.

In some cases, the memory cells storing the ECC bits are written to more frequently than the memory cells storing the user bits. For example, when performing a write command on certain bits within a set of user bits, all of the corresponding ECC bits may need to be updated when only a few of the user bits need to be updated. This results in certain memory cells being written to more frequently than others, and thus, the memory cells that are written to more frequently wear out quicker than the memory cells that are written to less frequently.

Wear-leveling is typically performed to reduce the wearing of certain memory cells that would otherwise be written to more frequently than other memory cells. Wear-leveling typically involves moving large blocks of data (thousands of bits) to different memory locations at certain time intervals. However, there is currently no mechanism for performing fine grained wear-leveling on specific bits within the large blocks of data. Current mechanisms for wear-leveling also do not take into account the corresponding ECC bits that may change more frequently that the user bits.

Disclosed herein are methods and systems to implement wear-leveling on the memory cells that store the user bits and the ECC bits based on a write count for a portion of the memory that stores the user bits. The wear-leveling is performed by shifting or rotating the user bits and the ECC bits by a circular shifter offset, which is computed according to the write count. Wear-leveling is also performed on the write count bits by performing balanced gray code (BGC) encoding on the write count bits.

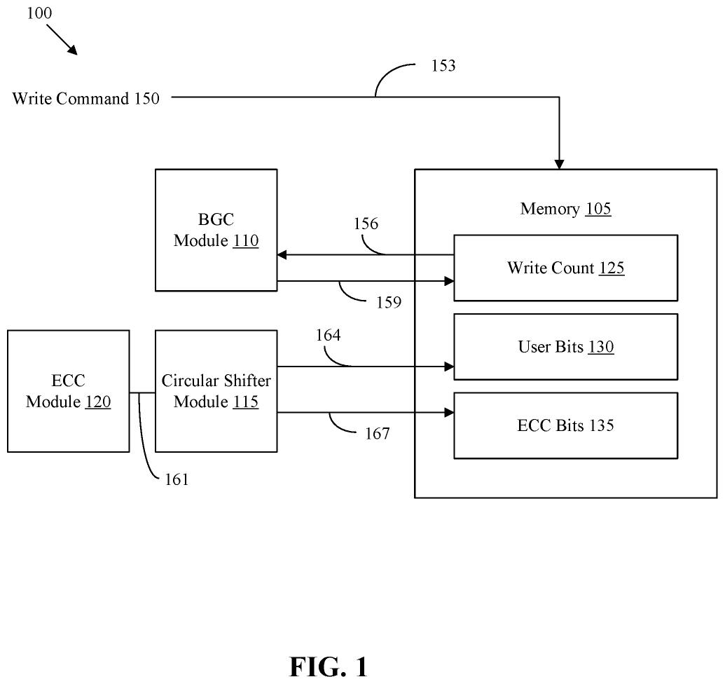

FIG. 1 is a diagram illustrating an example of a memory system 100 configured to perform wear-leveling according to various embodiments of the disclosure. The memory system 100 includes a memory 105 that is configured to store a write count 125, user bits 130, and ECC bits 135, which is further described below. The memory system 100 also includes a BGC module 110 (also referred to herein as a BGC engine), a circular shifter module 115 (also referred to herein as a circular shifter), and an ECC module 120 (also referred to herein as an ECC engine). The BGC module 110, circular shifter module 115, and ECC module 120 may each be a set of computer executable instructions that are stored within the memory system 100 such that, when executed, cause the memory system 100 to perform wear-leveling in a fine-grained manner on the memory 105, as will be further described below.

The memory 105 comprises multiple memory cells, each of which is a minimum physical unit configured to store data. Each memory cell within memory 105 may be configured to store any number of bits. For example, a memory cell within memory 105 may be configured to store a single bit of data, two bits of data, or four bits of data. An aggregation of four bits of data is also referred to herein as a nibble.

The memory cells within memory 105 may be configured to store many different types of data. As shown by FIG. 1, the memory 105 is configured to store user bits 130, which refers to bits of user data. The memory 105 is also configured to store ECC bits 135, which refers to bits that are used to perform error detection and correction on the user bits 130.

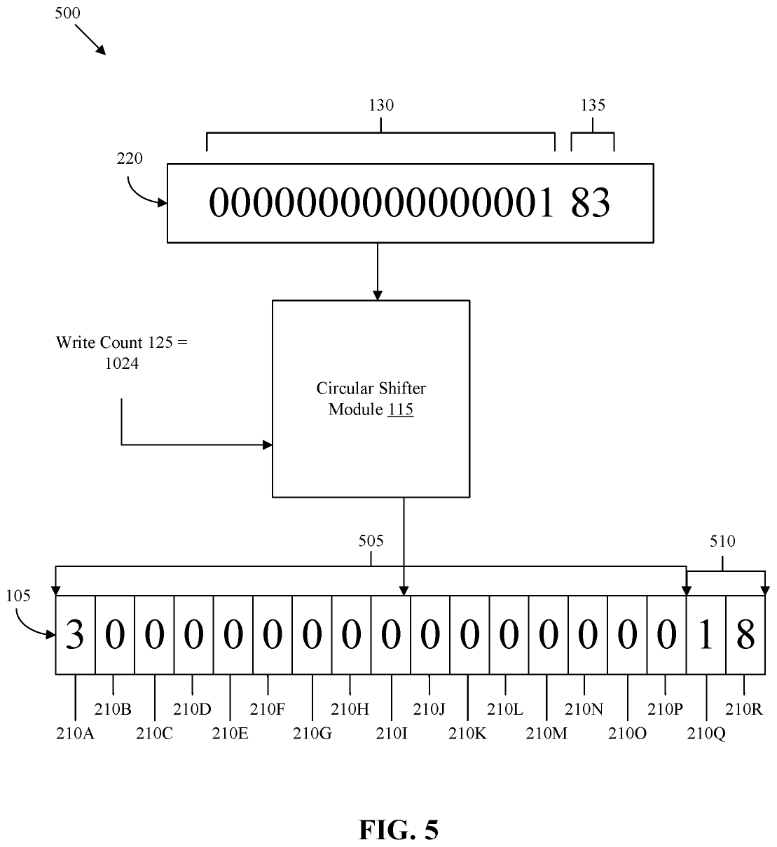

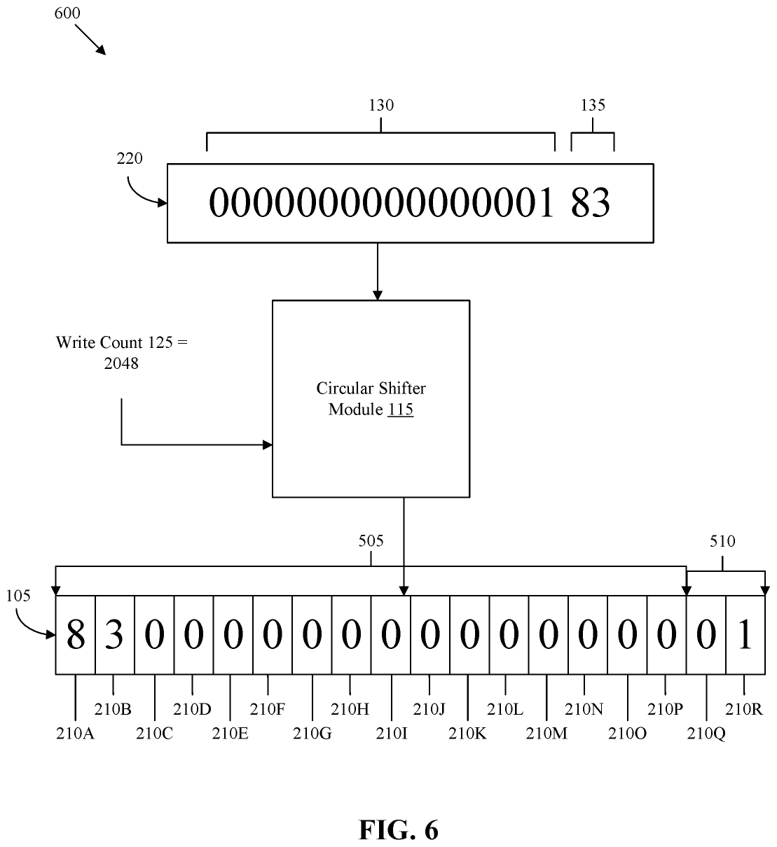

The memory 105 may be logically divided into multiple codewords, in which each codeword includes both a block of user bits 130 (also referred to herein as a plurality of user bits 130 or simply user bits 130) and ECC bits 135 that correspond to the user bits 130. The block of user bits 130 is typically stored at a first portion of the memory 105, while the block of ECC bits 135 is typically stored at a second portion of the memory 105, as will be further described below with reference to FIGS. 5 and 6. When discussing the user bits 130 and ECC bits 135 of a codeword, the ECC bits 135 may be considered as logically stored together with the corresponding block of user bits 130. However, the ECC bits 135 may actually be stored separately and non-contiguously from the corresponding block of user bits 130.

The block of user bits 130 in a codeword may be physically stored within the first portion of the memory 105 at one or more contiguous memory cells or one or more non-contiguous memory cells. The block of user bits 130 may be associated with a physical address indicating a location of the one or more memory cells storing the block of user bits 130. The block of user bits 130 may also be associated with a logical address, which is similar to the physical address in that the logical address indicates a location of the one or more memory cells storing the block of user bits 130. However, while the physical address of the block of user bits 130 may change over time, the logical address of the block of user bits 130 does not change over time.

The physical address of the block of user bits 130 may be associated with a write count 125, which refers to an integer value indicating a number of times that the physical address of the block of user bits 130 has been accessed (written to or read). The write count 125 may also refer to an integer value indicating a number of times a write command 150 has been received and executed on the physical address of the block of user bits 130. As shown by FIG. 1, the memory 105 may separately store the write count 125 for various blocks of user bits 130. The write count 125 may be considered as logically stored together with the corresponding block of user bits 130. However, the write count 125 may actually be stored physically separate and non-contiguously from the corresponding block of user bits 130.

The ECC bits 135 may be physically stored within the second portion of the memory 105 at one or more contiguous memory cells or one or more non-contiguous memory cells. The ECC bits 135 may also be associated with a physical address and a logical address. In some embodiments, each of the bits within the user bits 130 and the ECC bits 135 have a corresponding physical address, which may change over time, or a logical address, which remains the same.

The memory 105 may be a storage class memory (SCM), which is a nonvolatile storage technology using low cost materials such as chalcogenides, perovskites, phase change materials, magnetic bubble technologies, carbon nanotubes, etc. For example, memory 105 may be an SCM such as a 3-Dimensional (3D) CrossPoint (XPoint) memory, a phase-change Random Access Memory (RAM), or any Resistive RAM. Memory 105 may be configured to store permanently due to the nonvolatile characteristics of SCMs. Memory 105 is also bit-alterable, similar to a DRAM, which allows a user or administrator to change the data on a per-bit basis.

However, unlike DRAM and disk drives, an SCM such as memory 105 has a limited life span in which only a maximum threshold number of operations may be performed on a memory cell before the memory cell is worn out and no longer functional for storing data. For example, SCMs may only be capable of supporting 10⁶ to 10¹² operations on a memory cell before a memory cell may no longer be used to store data.

Some memory cells wear out faster than other memory cells because some memory cells are written to and read from much more frequently than others. When some cells are effectively worn out while other cells are relatively unworn, the existence of the worn out cells generally compromises the overall performance of the memory system 100. In addition to degradation of performance associated with the worn out memory cells, the overall performance of the memory system 100 may be adversely affected when an insufficient number of memory cells which are not worn out are available to store desired data. Often, a memory system 100 may be deemed unusable when a critical number of worn out cells are present in the memory system 100, even when many other cells are relatively unworn.

To increase the likelihood that memory cells within a memory system 100 are worn fairly evenly, wear-leveling operations are often performed. Wear-leveling operations involve changing the location of data periodically within a memory 105 such that the same data is not always stored at the same memory cells. By changing the data stored at each of memory cells, it is less likely that a particular memory cell may wear out well before other cells wear out.

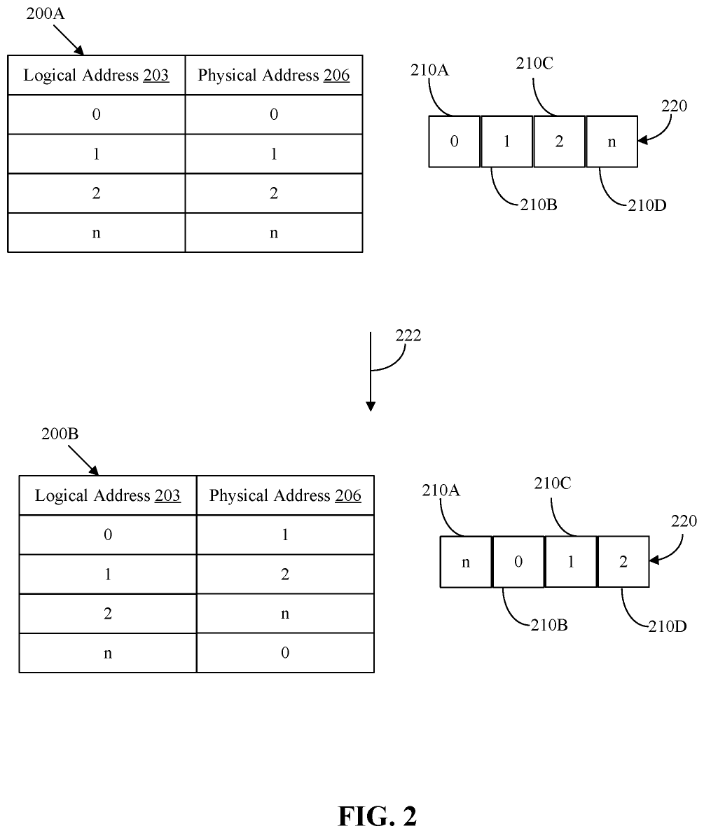

Wear-leveling is typically performed by changing the physical address of data periodically without changing the logical address of the data. For example, wear-leveling is performed by changing the physical address of user bits 130 without changing the logical address of the user bits 130, as will be further described below with reference to FIG. 2. However, typical methods of wear-leveling are performed on a memory 105 in a coarse-grained manner in which thousands of bits change locations during one iteration of wear-leveling. For example, one iteration of wear-leveling typically involves changing locations of thousands of bits, such as 1,000 (1K) bits or 4,000 (4K) bits, to prevent the cells from wearing unevenly. However, such a coarse-grained method of wear-leveling does not efficiently prevent the wearing out of particular memory cells and does not take into account ECC bits 135 that are associated with the user bits 130.

The embodiments disclosed herein are directed to performing wear-leveling on a memory 105 in a fine-grained manner by changing the locations of user bits 130 and ECC bits 135 based on a value of a write count 125. The embodiments disclosed herein perform wear-leveling on a bit (e.g., 1 bit) or nibble (e.g., 4 bits) level between the user bits 130 and the ECC bits 135. In operation, as shown by arrow 153, the memory system 100 may receive a write command 150 from a user. The write command 150 may include user bits 130 that are to be written to the memory 105 and an address at which to write the user bits 130. In an embodiment, the address included in the write command 150 may be the physical address of the first portion of memory 105 configured to store the user bits 130 in the write command 150. In an embodiment, the address included in the write command 150 may be the logical address of a codeword (user bits 130 and corresponding ECC bits 135) indicating a location of where the user bits 130 may be stored in the memory 105.

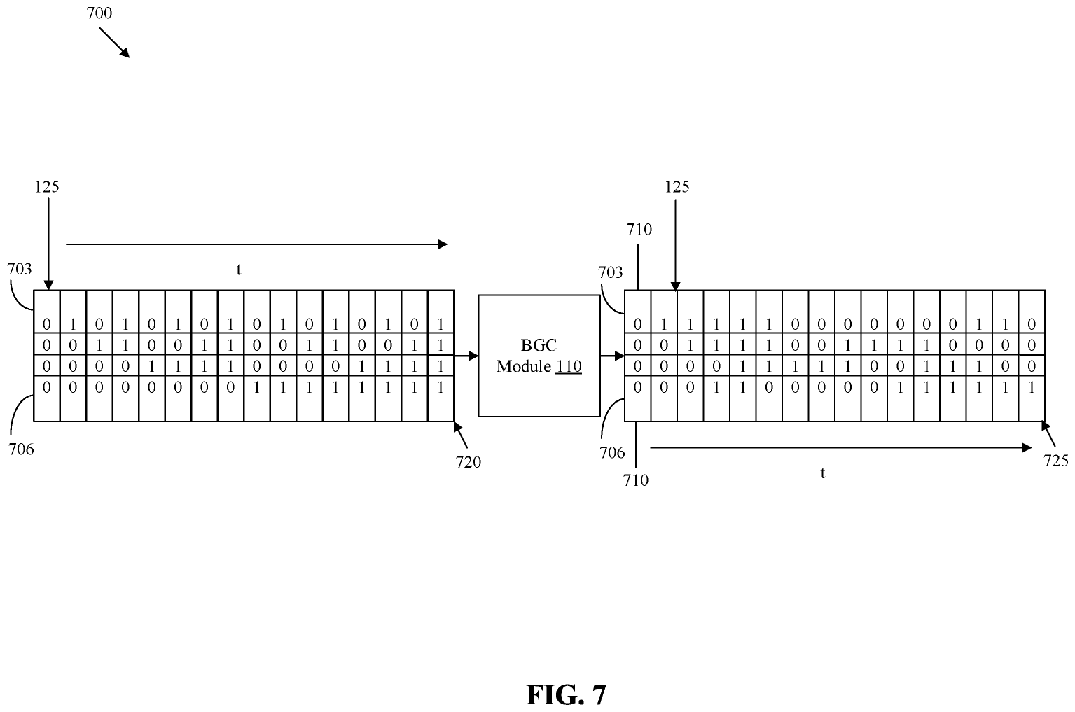

In an embodiment, as shown by arrow 156, BGC module 110 first obtains the write count 125 corresponding to the address included in the write command 150 after receiving the write command 150. The BGC module 110 is then configured to increment the write count 125 by one in response to receiving the write command 150. After incrementing the write count 125, the BGC module 110 is configured to encode the write count bits of the write count 125 such that each of the memory cells of the memory 105 storing the write count 125 is written to a substantially equal number of times, as will be further described below with reference to FIG. 7.

As shown by arrow 159, the memory system 100 is configured to store the write count bits of the write count 125 at a pre-defined memory location after incrementing and BGC encoding the write count 125. In this way, the BGC encoded and incremented write count 125 may be accessed by the circular shifter module 115.

The ECC module 120 is configured to compute the ECC bits 135 for the corresponding user bits 130 in the write command 150. For example, the ECC module 120 may be configured to use an error correction algorithm to compute the ECC bits 135. The ECC bits 135 are typically used to detect and correct errors that are introduced into the user bits 130 through transmission and storage. For example, the ECC module 120 may also be configured to perform error correction for the user bits 130 based on the ECC bits 135 and a stored ECC. The ECC bit 135 computation and the error correction mechanisms performed by the ECC module 120 are further described in the IEEE document entitled “A High-Speed Two-Cell BCH Decoder for Error Correcting in MLC NOR Flash Memories,” by Wang Xueqiang, et. al.

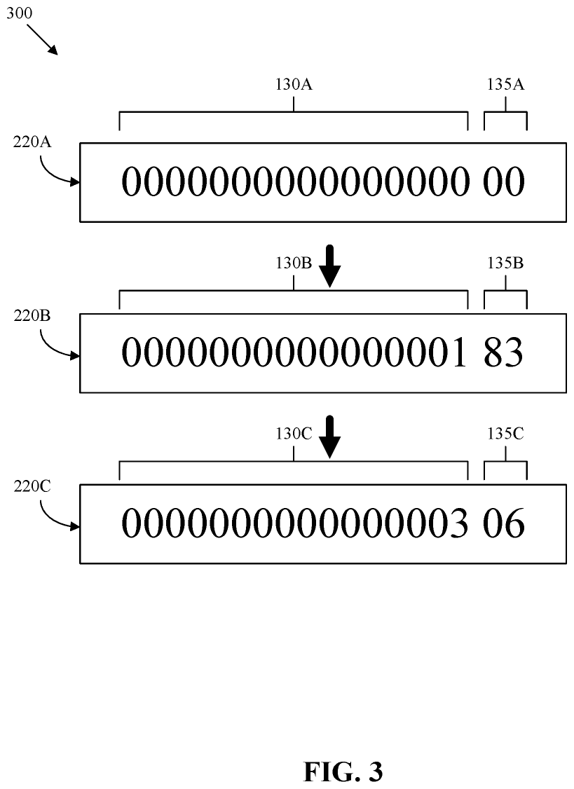

As shown by arrow 161, the circular shifter module 115 may obtain the ECC bits 135 computed by the ECC module 120. The circular shifter module 115 is then configured to determine locations of memory cells for storing specific bits of the codeword including user bits 130 from the write command 150 and the computed ECC bits 135. In an embodiment, the circular shifter module 115 is configured to store the user bits 130 and the corresponding ECC bits 135 at a rotated location to perform wear-leveling on the memory 105, as will be further described below with reference to FIGS. 3-6. As shown by arrow 164, the circular shifter module 115 is configured to write the individual bits or nibbles of the user bits 130 to particular memory cells within both the first portion of the memory 105 and the second portion of the memory 105. Similarly, as shown by arrow 167, the circular shifter module 115 is configured to write individual bits or nibbles of the ECC bits 135 to particular memory cells within both the first portion of the memory 105 and the second portion of the memory 105.

In an embodiment, the circular shifter module 115 is configured to determine locations of memory cells for storing of the user bits 130 and ECC bits 135 of a codeword using a circular shifter offset, which is computed based on the write count 125, as will be further described below with reference to FIGS. 5 and 6. For example, suppose the write count 125 for the first portion of the memory 105 configured to store the user bits 130 corresponds to a circular shifter offset of 1, then the circular shifter module 115 rotates the storage of the user bits 130 and the ECC bits 135 within the first portion of the memory 105 and the second portion of the memory 105 by 1. In such a case, the memory 105 is configured to shift all the user bits 130 and the ECC bits 130 to the right by one memory cell. In this case, the last bit or nibble of the codeword is shifted to be stored at the position where the first bit of the codeword was positioned. In this way, the write count 125 may correspond to various different circular shifter offsets that instruct the circular shifter module 115 to rotate the storage of the user bits 130 and the ECC bits 135 by a variable amount.

According to various embodiments, the BGC module 110, circular shifter module 115, and the ECC module 120 work together to implement fine-grained wear-leveling on the memory cells storing particular bits or nibbles of a codeword including user bits 130 and corresponding ECC bits 135. The fine-grained wear-leveling changes the location of storing particular bits or nibbles of data, rather than large blocks of thousands of bits of data, resulting in a more precise and accurate manner of controlling the lifespan of memory cells within memory 105.

FIG. 2 is a diagram illustrating a relationship between physical addresses 206 and logical addresses 203 of memory cells 210 in a memory according to various embodiments of the disclosure. Tables 200A-B include a column for the logical addresses 203 for a codeword 220, which may include user bits 130 and ECC bits 135, and a column for the physical addresses 206 for the codeword 220. The tables 200A-B show how user bits 130 and ECC bits 135 may be stored in particular memory cells 210A-D before and after wear-leveling is performed on the memory cells 210A-D. The block diagrams to the right of the tables 200A-B illustrate the storage of bits within the codeword 220 in particular memory cells 210A-D within the memory 105 before and after wear-leveling is performed on the memory cells 210A-D.

As shown by FIG. 2, memory cell 210A may have a physical address 206 of 0, memory cell 210B may have a physical address 206 of 1, memory cell 210C may have physical address 206 of 2, and memory cell 210D may have a physical address 206 of n. For the example shown in FIG. 2, suppose the first bit of the codeword 220 is a user bit 130 having a logical address 203 of 0, the second bit of the codeword 220 is a user bit 130 having a logical address 203 of 1, the third bit of the codeword 220 is a user bit 130 having a logical address 203 of 3, and the fourth bit of the codeword 220 is an ECC bit 135 having a logical address 203 of 4. When wear-leveling is performed on the codeword 220, the physical address 206 indicating an actual physical location of the bits within the codeword 220 may change, while the logical address 203 remains the same.

In particular, table 200A shows a default mapping between a logical address 203 of bits (or nibbles) within a codeword 220 and a physical address 206 indicating the memory cells 210A-D that store the bits or nibbles within the codeword 220 before wear-leveling is performed on the memory 105. As shown by table 200A, by default, the logical address 203 and the physical address 206 for bits within the codeword 220 match up, or are the same. Table 200A shows that the user bit 130 corresponding to the logical address 203 of 0 is stored at the memory cell 210A having a physical address 206 of 0, the user bit 130 corresponding to the logical address 203 of 1 is stored at the memory cell 210B having a physical address 206 of 1, the user bit 130 corresponding to the logical address 203 of 2 is stored at the memory cell 210C having a physical address 206 of 2, and the ECC bit 135 corresponding to the logical address 203 of n is stored at the memory cell 210D having a physical address 206 of n. The user bits 130 corresponding to the logical addresses 203 of 0-2 may be stored at a first portion of the memory 105, while the ECC bit 135 corresponding to the logical address 203 of n may be stored at a second portion of the memory 105.

After wear-leveling is performed, as shown by arrow 222, the physical addresses 206 of the bits within the codeword 220 change (e.g., shift or rotate) by a certain number of memory cells 210A-D. As shown by FIG. 2, the bits within the codeword 220 are rotated to the right by one memory cell 210. Table 200B shows that the user bit 130 corresponding to the logical address 203 of 0 is now stored at the memory cell 210B having a physical address 206 of 1, the user bit 130 corresponding to the logical address 203 of 1 is now stored at the memory cell 210C having a physical address 206 of 2, the user bit 130 corresponding to the logical address 203 of 2 is now stored at the memory cell 210D having a physical address 206 of n, and the ECC bit 135 corresponding to the logical address 203 of n is now stored at the memory cell 210A having a physical address 206 of 0. In this way, after wear-leveling is performed within the codeword 220, the physical addresses 206 of each of the bits within the codeword 220 changes, while the logical addresses 203 of each of the bits within the codeword 220 remains the same.

While only four memory 210A-D cells are shown as storing the codeword 220, it should be appreciated that the codeword 220 may include any number of bits stored in any number of memory cells 210A-D. Each of the memory cells 210A-D may also store any number of user bits 130 or ECC bits 135. While each of memory cells 210A-D in FIG. 2 are shown to store a bit within a user bit 130 or ECC bit 135, it should be appreciated that each of the memory cells 210A-D in FIG. 2 may also be configured to store two bits or a nibble instead. While each of the memory cells 210A-D are shown in FIG. 2 as being contiguous and adjacent, it should be appreciated that each of the memory cells 210A-D may be separate and non-contiguous.

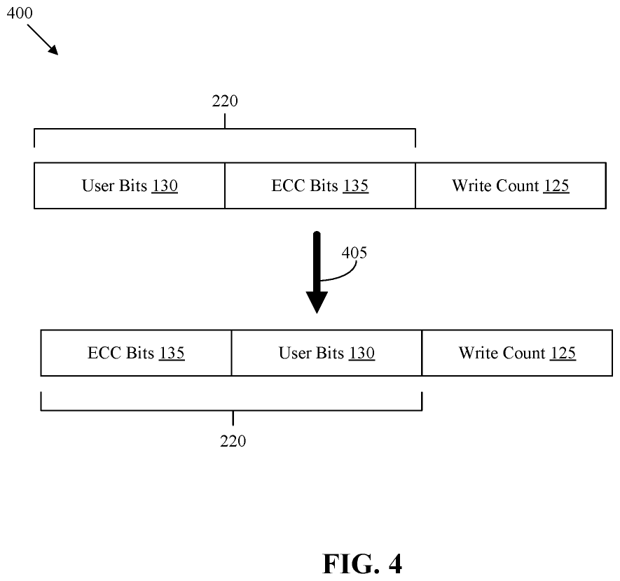

While FIG. 2 shows that the bits within the codeword 220 shift by only a single memory cell 210, in some embodiments, the bits within the codeword 200 may shift by any number of memory cells 210 depending on a write count 125 of the codeword 220, which will be further described below with reference to FIGS. 5 and 6. The number of memory cells 210 by which to perform wear-leveling within the codeword 220 is also referred to as a circular shifter offset, which is further described below with reference to FIG. 4.

As should be appreciated tables 200A-B may not actually need to be stored at the memory system 100. Instead, the memory system 100 may use other data structures to store a mapping between the logical address 203 and physical address 206 of user bits 130. As shown by FIG. 2, the embodiments disclosed herein enable performing wear-leveling on a bit level or nibble level basis. The embodiments disclosed herein account for the wearing of memory cells 210 storing ECC bits 135, which may change much more frequently than the corresponding user bits 130, as described below with reference to FIG. 3.

FIG. 3 is a diagram 300 illustrating a difference between the ECC bits 135 of a codeword 220 and user bits 130 of the codeword 220 according to various embodiments of the disclosure. In particular, diagram 300 shows the user bits 130A-C and the ECC bits 135A-C in a codeword 220A-C being updated in response to two write commands 150 being performed on the codeword 220A-C.

Codeword 220A may represent an initial setting of the memory cells 210, in which codeword 220A includes the user bits 130A of “0000000000000000” and corresponding ECC bits of 135A “00.” In an embodiment, the user bits 130A may be stored at a first portion of the memory 105 while the ECC bits 135A are stored at a second portion of the memory 105. The first portion of the memory 105 and the second portion of the memory 105 may be non-contiguous and separate locations within the memory 105.

A first write command 150 may be performed on the codeword 220A to generate codeword 220B, which includes the user bits 130B of “0000000000000001” and corresponding ECC bits 135A of “83.” Similar to codeword 220A, the user bits 130B may be written to the first portion of the memory 105, and the ECC bits 135B may be written to the second portion of the memory 105.

A write ratio refers to a ratio between a number of bits changed to a total number of bits. A write ratio of the user bits 130A-C is frequently less than a write ratio for the ECC bits 135A-C. As shown by FIG. 3, only one bit of the 16 user bits 130B changed in response to the first write command 150, while both of the ECC bits 135B changed in response to the first write command 150. Therefore, the ECC bits 135B have a higher write ratio (e.g., number of bits updated/total bits) than the user bits 130B in response to the first write command 150.

A second write command 150 may be performed on the codeword 220B to generate codeword 220C, which includes user bits 130C of “0000000000000003” and corresponding ECC bits 135C of “06.” Similar to codewords 220A-B, the user bits 130C may be written to the first portion of the memory 105, and the ECC bits 135C may be written to the second portion of the memory 105.

Similar to codeword 220B, only one bit of the 16 user bits 130C changed in response to the second write command 150, while both of the ECC bits 135C changed in response to the first write command 150. Therefore, the ECC bits 135C also have a higher write ratio (e.g., number of bits updated/total bits) than the user bits 130C in response to the second write command 150.

The nature of control bits, such as ECC bits 135A-C, that manage the storage of data within a memory 105 are such that the control bits change much more frequently than the actual user bits 130A-C. However, memory cells 210 storing control bits such as ECC bits 135A-C are typically not wear-levelled to account for the increased wear that may occur on these memory cells 210. As described above and below, the embodiments disclosed herein perform wear-leveling on the user bits 130A-C and the ECC bits 135A-C to account for the increased wear that occurs on memory cells 210 storing ECC bits 135A-C.

As should be appreciated, diagram 300 is described in a manner such that each memory cell 210 stores a bit of data. However, it should be appreciated that the embodiments discussed herein may be implemented such that each memory cell 210 stores either two bits of data, a nibble of data, or any other number of bits of data.

FIG. 4 is a diagram illustrating a method 400 of wear-leveling according to various embodiments of the disclosure. FIG. 4 shows a codeword 220, including user bits 130 and ECC bits 135, and a corresponding write count 125 of first portion of the memory 105 configured to store the user bits 130 within the codeword 220. As should be appreciated, while the user bits 130, ECC bits 135, and write count 125 are shown in FIG. 4 as being contiguously stored adjacent to one another, the user bits 130, ECC bits 135, and write count 125 may be stored non-contiguously and in separate locations of memory 105. The bits within the user bits 130, ECC bits 135, and write count 125 may also be stored contiguously or non-contiguously within memory 105. In an embodiment, the user bits 130 and the ECC bits 135 may be logically stored together and consecutively, and the bits within the user bits 130 and the ECC bits 135 may also be logically stored together and consecutively.

Method 400 illustrates the location of the user bits 130, ECC bits 135, and write count 125 as wear-leveling 405 (also referred to herein as circular shifting) is performed. In an embodiment, performing wear-leveling 405 involves shifting a physical address at which to store each of the bits within the user bits 130 and the ECC bits 135 according to a circular shifter offset, which is calculated based on the write count and further described below with reference to FIGS. 5 and 6. In this embodiment and as shown by FIG. 4, the user bits 130 and the ECC bits 135 change locations (e.g., rotate or shift) to be stored at different memory cells 210 after performing wear-leveling 405. Further details of the movement of bits within the codeword 220 while performing wear-leveling 405 will be further described below with reference to FIGS. 5 and 6.

However, the location of the write count 125 remains the same and does not change after performing wear-leveling 405. The memory cells storing the write count 125 are still managed by the BGC module 110 to prevent certain memory cells storing the bits within the write count 125 from wearing out before others, as will be further described below with reference to FIG. 7.

FIG. 5 is a diagram illustrating an example of a method 500 for performing wear-leveling according to various embodiments of the disclosure. Specifically, method 500 illustrates how a codeword 220 is stored in memory cells 210A-R after performing wear-leveling according to a write count 125. The codeword 220, or the data that is to be stored in the memory 105, includes 16 user bits 130 (“0000000000000001”) and two ECC bits 135 (“83”). The user bits 130 may be received in a write command 150 and extracted from the write command 150. The ECC bits 135 may be calculated by the ECC module 120 based on the user bits 130.

The codeword 220 may be stored in a first portion 505 of the memory 105 and a second portion 510 of the memory 105. The first portion 505 and the second portion 510 may be contiguous and adjacent to one another or non-contiguous and separate from one another. Typically, the user bits 130 are stored in the first portion 505, while the ECC bits 135 are stored in the second portion 510. The embodiments disclosed herein enable user bits 130 to be stored in the second portion 510 and ECC bits 135 to be stored in the first portion 505.

Upon receiving the write command 150 comprising the user bits 130 and computing the corresponding ECC bits 135, the write count 125 for an address of the first portion 505 of the memory 105 at which the user bits 130 are to be stored may be incremented by one. In an embodiment, the write count 125 for various blocks of memory 105 may be stored at a third portion of the memory 105, separate from the first portion 505 of the memory 105 storing the user bits 130 and the second portion 510 of the memory 105 storing the ECC bits 135. As shown in the example method 500, the write count 125 for the first portion 505 of memory 105 at which to store the user bits 130 is incremented by one to be 1024 after receiving the write command 150. As will be further described below with reference to FIG. 7, the write count 125 will be further encoded using BGC encoding before being stored in the memory 105.

After incrementing the write count 125 of the first portion 505 of the memory 105 to which the user bits 130 will be stored, the circular shifter module 115 may determine the memory cells 210A-R where the user bits 130 and the ECC bits 135 will be stored based on the write count 125. By default, the user bits 130 may be stored at memory cells 210A-P of the first portion 505 of the memory 105, and the ECC bits 135 may be stored at memory cells 210Q-R of the second portion 510 of the memory 105 in the same sequence as shown by codeword 220 of FIG. 5. As described above, the first portion 505 of the memory 105 and the second portion 510 of the memory 105 may be non-contiguous blocks of memory cells 210A-R within the memory 105.

However, as described above, memory cells 210A-R may be written to and accessed a different number of times, which leads to certain memory cells 210A-R wearing out before other memory cells 210A-R. To prevent this uneven wearing of the memory cells 210A-R of the memory 105, the circular shifter module 115 is configured to perform wear-leveling by adjusting how the bits are stored at the first portion 505 and the second portion 510 in the memory 105 based on a circular shifter offset. A circular shifter offset is an integer value that represents a number of memory cells 210A-R within the first portion 505 and the second portion 510 of the memory 105 by which to shift the user bits 130 and the ECC bits 135 before writing the user bits 130 and the ECC bits 135 to the memory cells 210A-R within the first portion 505 and the second portion 510 of the memory 105.

In an embodiment, a circular shifter offset is a function of the write count 125 and is applied to data during write and read commands. In some embodiments, the circular shifter offset is equal to Integer(write count 125/K), where K is a predefined constant associated with the write count 125. In some embodiments, the circular shifter offset may be any value that is a function of the write count 125. For example, the circular shifter offset may be equal to the Integer(a*log(write count)+b), where a and b are predefined constants.

Suppose that K=1024 in the example method 500 shown in FIG. 5. In this case, the circular shifter module 115 is configured to determine that circular shifter offset is one (Integer (1024/1024)). The circular shifter module 115 may then determine that the storage of the user bits 130 and the ECC bits 135 should be shifted to the right by one memory cell 210A-R since the circular shifter offset is one.

As shown in FIG. 5, the circular shifter module 115 shifts all of the user bits 130 and the ECC bits 135 to the right by one memory cell 210A-R such that the last bit of “3” moves to the location of the memory cell 210A. Memory cell 210A by default would have stored the first user bit 130 of “0”, but instead, stores an ECC bit 135 of “3” due to the wear-leveling performed by the circular shifter module 115. Similarly, memory cells 210B-Q store the user bits 130 that have been shifted to the right by one memory cell, and memory cell 210R stores an ECC bit 135 of “8” instead of the ECC bit 135 of “4” due to the wear-leveling performed by the circular shifter module 115.

In some embodiments, the circular shifter module 115 is configured to rotate the storage of the user bits 130 and the ECC bits 135 according to the circular shifter offset on a bit level, nibble level, fractional-nibble level, or multiple-nibble level. Examples of circular shifter offsets on a multiple-nibble level include when the circular shifter offset is equal to multiples, such as, for example, 2, 4, or 8 nibbles, when the write count 125 is 1024. Examples of circular shifter offsets on a fractional-nibble level include when the circular shifter offset is equal to fractions, such as, for example, ¼ or ½ of a nibble, when the write count 125 is 1024. In this way, the circular shifter module 115 is configured to determine the specific memory cells 210A-R at which to store the user bits 130 and the ECC bits 135 on a nibble level, a fractional-nibble level, or multiple-nibble level.

While typically the user bits 130 are stored in the first portion 505 of the memory 105 and the ECC bits 135 are stored in the second portion 510 of the memory 105, the embodiments of wear-leveling disclosed herein enable ECC bits 135 to be stored in the first portion 505 of the memory 105 as well as the second portion 510 of the memory 105. Similarly, the embodiments of wear-leveling disclosed herein enable the user bits 130 to be stored in the second portion 510 of the memory 105 as well as the first portion 505 of the memory 105. While this example shown in FIG. 5 illustrates the circular shifter offset being one bit, it should be appreciated that the circular shifter offset may otherwise be one nibble, multiple bits, or multiple nibbles.

FIG. 6 is a diagram illustrating another example of a method 600 for performing wear-leveling according to various embodiments of the disclosure. Method 600 is similar to method 500, except that the write count 125 of the first portion 505 of the memory 105 is 2048 instead of 1024. The write count 125 of 2048 is computed after receiving the write command 150 comprising the user bits 130 and computing the ECC bits 135 based on the user bits 130. The write count 125 of 2048 that is used to determine the circular shifter offset may have also been incremented by one in response to receiving the write command 150. The write count 125 of 2048 may be stored in the memory 105 separate from the first portion 505 of the memory 105 and the second portion 510 of the memory 105.

In an embodiment, the circular shifter module 115 may determine the memory cells 210A-R at which to store each of the user bits 130 and the ECC bits 135 based on the write count 125. As described above with reference to FIG. 5, by default, the user bits 130 may be stored at memory cells 210A-P of the first portion 505 of the memory 105, and the ECC bits 135 may be stored at memory cells 210Q-R of the second portion 510 of the memory 105 in the same sequence as shown by codeword 220. However, since the write count 125 of 2048 for the first portion 505 of the memory 105 is relatively high, wear-leveling may be performed based on a computed circular shifter offset.

As described above with reference to FIG. 5, the circular shifter offset may be calculated in a variety of ways. Assuming that the circular shifter offset is again computed based on an Integer(write count 125/K), where K=2048, then the circular shifter offset may equal two. The circular shifter module 115 may then determine that the storage of the user bits 130 and the ECC bits 135 should be shifted to the right by two memory cells 210A-R since the circular shifter offset is two.

As shown in FIG. 6, the circular shifter module 115 shifts all of the user bits 130 and the ECC bits 135 to the right by two memory cells 210A-R such that the last bit of “3” moves to the location of the memory cell 210B and the second to last bit of “8” moves to the location of the memory cell 210A. Memory cells 210A-B by default would have stored the first and second user bits 130 of “00”, but instead, stores an ECC bit 135 of “3” and a user bit 130 of “0” due to the wear-leveling performed by the circular shifter module 115. Similarly, memory cells 210B-Q store the user bits 130 that have been shifted to the right by one memory cell. Memory cell 210Q stores a user bit 130 of “1,” and memory cell 210R stores an ECC bit 135 of “8.”

As shown by FIGS. 5 and 6, the write count 125 and the constant K are the main factors used to compute the circular shifter offset, which corresponds to the number of memory cells 210A-R by which to shift the user bits 130 and ECC bits 135 within the first portion 505 and the second portion 510 of the memory 105. The embodiments of wear-leveling disclosed herein enable ECC bits 135 to be stored in the first portion 505 of the memory 105 as well as to the second portion 510 of the memory 105. Similarly, the embodiments of wear-leveling disclosed herein enable the user bits 130 to be stored in the second portion 510 of the memory 105 as well as to the first portion 505 of the memory 105. Therefore, the embodiments of wear-leveling disclosed herein extend the lifespan of memory cells 210A-R, and thus extends the lifespan of the entire memory 105. The embodiments of wear-leveling disclosed herein also enable fine-grained wear-leveling to be performed, in which the location within the memory 105 for storing bits or nibbles are changed instead of changing the locations of large blocks of data.

FIG. 7 is a diagram illustrating an example of a method 700 for performing wear-leveling on the memory cells 710 storing the write count 125 for a first portion 505 of memory 105 over time (t) according to various embodiments of the disclosure. As described above with reference to FIG. 1, the BGC module 110 obtains a write count 125 for a first portion 505 of the memory 105 at which user bits 130 included in a write command 150 should be written. After obtaining the write count 125, the BGC module 110 may increment the write count 125 for the first portion 505 of the memory 105. The box 720 on the left side of FIG. 7 represents the write count 125 for a first portion 505 of the memory 105 as it is incremented over time in response to receiving write commands 150. The box 725 on the right side of FIG. 7 represents the write count 125 for the first portion 505 of the memory 105 after incrementing and performing BGC encoding on the write count 125.

In an embodiment, the BGC module 110 is configured to perform BGC encoding on the write count 125 to re-encode the write count 125 such that the write count bits within the write count 125 are written to memory cells 710 in a substantially even manner. For this reason, the BGC module 110 performs wear-leveling on the write count bits according the BGC encoding to ensure that the write count bits are written and/or read a substantially equal number of times.

In both box 720 and box 725, the vertical columns represent the bits (or nibbles) of the write count 125 over time as the write count 125 is incremented. Each column within box 720 and 725 represents an update to the write count 125 over time. The horizontal columns represent the individual bits (or nibbles) within the write count 125 from least significant bit 703 to most significant bit 706. As shown in FIG. 7, the top row of box 720 and box 725 represents the least significant bit 703 of the write count 125, while the bottom row of box 720 and box 725 represents the most significant bit 706 of the write count 125.

As shown by box 720, the least significant bit 703 of the write count 125 changes every single time the write count 125 is incremented, while the most significant bit 706 of the write count 125 only changes once. The bits in the between the least significant bit 703 and the most significant bit 706 are also written to and/or read in an uneven manner. In this way, before BGC encoding is performed on the write count 125, the write count bits within the write count 125 are changed in an uneven manner, which causes the memory cells 710 storing these bits to wear out in an uneven manner.

According to some embodiments, the BGC module 110 performs BGC encoding on the bits within the write count 125 before storing the write count 125 to a third portion of the memory 105. Performing BGC encoding refers to changing the bits of the write count 125 to account for the memory cells 710 storing each of the bits of the write count 125 such that each of the memory cells 710 are written to and/or read in a substantially equal manner.

In an embodiment, after the BGC module 110 performs BGC encoding on the bits within the write count 125, the bits within the write count 125 change over time after incrementing in a more even manner. As shown by box 725, the least significant bit 703 changes four times, while the most significant bit 706 changes three times. In this way, after performing BGC encoding on the bits within the write count 125, the memory cell 710 storing the least significant bit 703 is written to less frequently, and the memory cell 710 storing the most significant bit 706 is written to more frequently. The memory cells 710 storing bits in between the least significant bit 703 and the most significant bit 706 are also written to in a more even manner after performing BGC encoding. In this way, performing BGC encoding on the bits within the write count 125 enables the bits to be updated in a more equal manner.

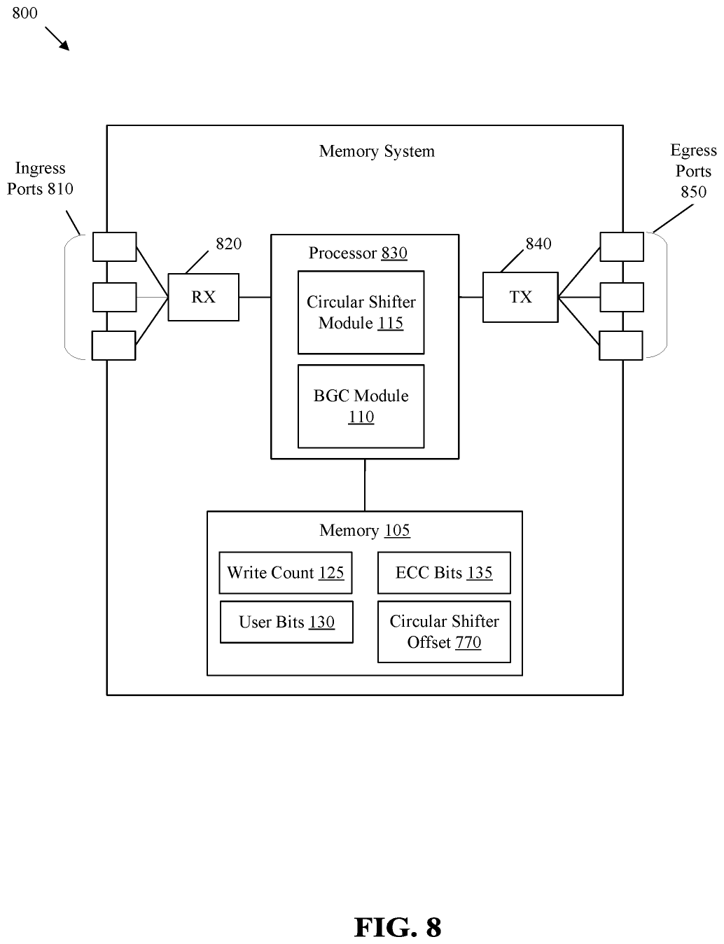

FIG. 8 is a diagram of an embodiment of a memory system 800 according to various embodiments of the disclosure. Memory system 800 may be similar to the memory system 100 shown in FIG. 1. The memory system 800 may be configured to implement and/or support the wear-leveling mechanisms described herein. The memory system 800 may be implemented in a single node or the functionality of memory system 800 may be implemented in a plurality of nodes. One skilled in the art will recognize that the term memory system encompasses a broad range of devices of which memory system 800 is merely an example. The memory system 800 is included for purposes of clarity of discussion, but is in no way meant to limit the application of the present disclosure to a particular memory system embodiment or class of memory embodiments. At least some of the features and/or methods described in the disclosure may be implemented in a network apparatus or module such as a memory system 800. For instance, the features and/or methods in the disclosure may be implemented using hardware, firmware, and/or software installed to run on hardware. As shown in FIG. 8, the memory system 800 comprises one or more ingress ports 810 and a receiver unit (Rx) 820 for receiving data, at least one processor, logic unit, or central processing unit (CPU) 830 to process the data, a transmitter unit (Tx) 840 and one or more egress ports 650 for transmitting the data, and a memory 105 for storing the data.

The processor 830 may comprise one or more multi-core processors and coupled to a memory 105, which may function as data stores, buffers, etc., similar to the memory described in FIG. 1. The processor 830 may be implemented as a general processor or may be part of one or more application specific integrated circuits (ASICs) and/or digital signal processors (DSPs). The processor 830 may comprise the circular shifter module 115 and the BGC module 110, which are each software instructions that are executable by the processor 830. As such, the inclusion of the circular shifter module 115, BGC module 110, and associated methods and systems provide improvements to the functionality of the memory system 800. Further, the circular shifter module 115 and BGC module 110 effect a transformation of a particular article (e.g., the network) to a different state. In an alternative embodiment, the circular shifter module 115 and the BGC module 110 may be implemented as instructions stored in the memory 105, which may be executed by the processor 830.

The memory 105 may be a storage class memory, similar to the memory 105 described in FIG. 1. The memory 105 may comprise a cache for temporarily storing content, e.g., a RAM. Additionally, the memory 105 may comprise a long-term storage for storing content relatively longer, e.g., a solid-state drive (SSD). For instance, the cache and the long-term storage may include DRAMs, SCMs, SSDs, hard disks, or combinations thereof. The memory 105 may be configured to store the write count 125, user bits 130, ECC bits 135, and circular shifter offset 770, as described herein.

It is understood that by programming and/or loading executable instructions onto the memory system 800, at least one of the processor 830 and/or memory 105 are changed, transforming the memory system 800 in part into a particular machine or apparatus, e.g., a multi-core forwarding architecture, having the novel functionality taught by the present disclosure. It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software network domain to the hardware network domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an ASIC, because for large production runs the hardware implementation may be less expensive than the software implementation. Often a design may be developed and tested in a software form and later transformed, by well-known design rules, to an equivalent hardware implementation in an ASIC that hardwires the instructions of the software. In the same manner as a machine controlled by a new ASIC is a particular machine or apparatus, likewise a computer that has been programmed and/or loaded with executable instructions may be viewed as a particular machine or apparatus.

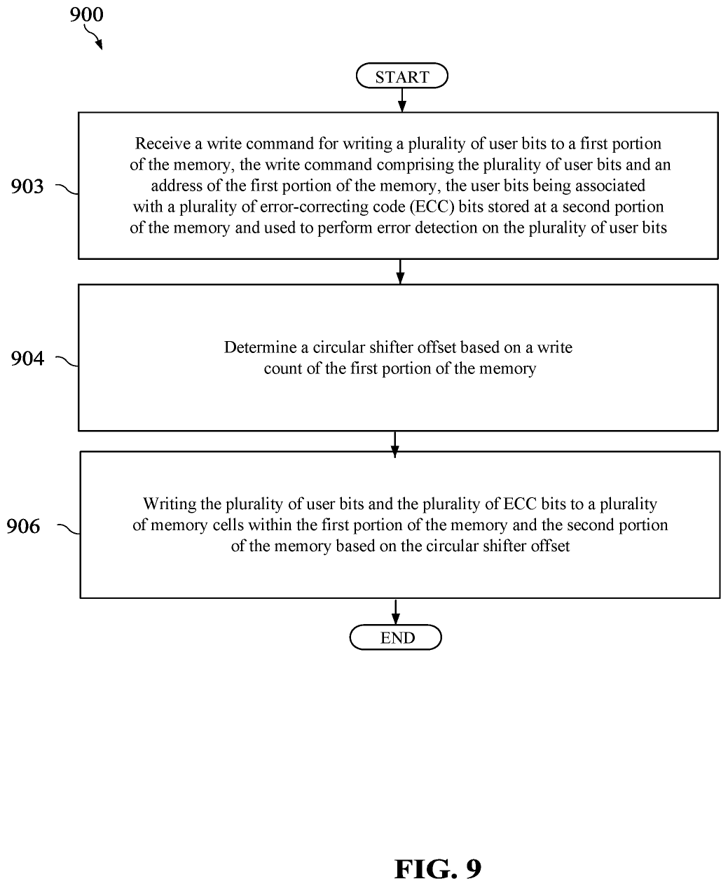

FIG. 9 is a flowchart illustrating a method 900 for performing wear-leveling on the memory 105 according to various embodiments of the disclosure. Method 900 may be performed by the memory system 100 or memory system 800. Method 900 may be implemented when a write command 125 is received by the memory system 100 or 800.

At step 903, a write command 150 for writing user bits 130 to a first portion 505 of the memory 105 is received. For example, Rx 820 receives the write command 150. In an embodiment, a write command 150 comprises the user bits 130 and an address (physical address or logical address) of the first portion 505 of the memory 105. In an embodiment, the user bits 130 are associated with a plurality of ECC bits 135 stored at a second portion 510 of the memory 105 and used to perform error detection on the user bits 130.

At step 905, a circular shifter offset 770 is determined based on a write count 125 of the first portion 505 of the memory 105. For example, the processor 830 determines the circular shifter offset 770 based on the write count 125, as described above with reference to FIGS. 5 and 6. The circular shifter offset 770 may be stored in the memory 105 or anywhere within the memory system 100 or 800.

At step 906, the user bits 130 and the ECC bits 135 are written to memory cells 210 within the first portion 505 of the memory 105 and the second portion 510 of the memory 105 based on the circular shifter offset 770. For example, the processor 830 may execute the circular shifter module 115 to write the user bits 130 and ECC bits 135 to memory cells 210 within the first portion 505 of the memory 105 and the second portion 510 of the memory 105 based on the circular shifter offset 770.

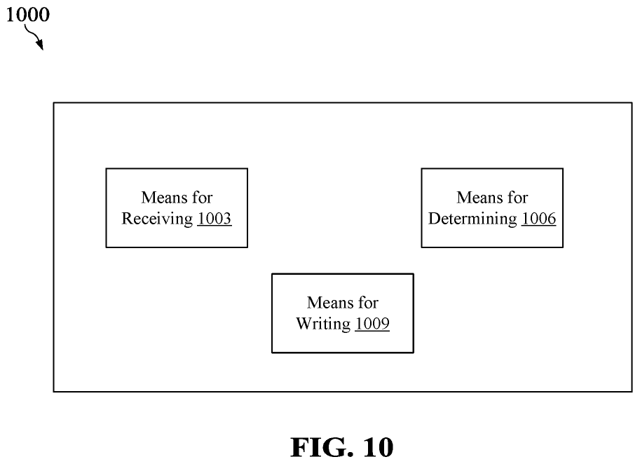

FIG. 10 is a diagram illustrating an apparatus 1000 configured to perform wear-leveling on the memory 105 according to various embodiments of the disclosure. Apparatus 100 comprises a means for receiving 1003, a means for determining 1006, and a means for writing 1009. The means for receiving 1003 is configured to receive a write command 150 for writing a plurality of user bits 130 to a first portion 505 of the memory 105, the write command 150 comprising the plurality of user bits 130 and an address of the first portion 505 of the memory 105, the user bits 130 being associated with a plurality of ECC bits 135 stored at a second portion 510 of the memory 105 and used to perform error detection on the plurality of user bits 130. The means for determining 1006 is configured to determine a circular shifter offset 770 based on a write count 125 of the first portion 505 of the memory 105. The means for writing 1009 is configured to write the plurality of user bits 130 and the plurality of ECC bits 135 to a plurality of memory cells 210 within the first portion 505 of the memory 105 and the second portion 510 of the memory 105 based on the circular shifter offset 770.

The systems, methods, and apparatuses described herein provide a mechanism for rotation between ECC bits and user bits at a bit and/or nibble level. The write count 125 based circular shifter functions to provide a mechanism to change the rotation frequency as a function of the write count 125 recorded after each write command 150. The bits within the write count 125 are self-wear-leveled with BGC encoding. The systems, methods, and apparatuses disclosed herein fully utilize the SCM bit alteration functions for energy, endurance, and performance purposes.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A method of performing wear-leveling on a memory implemented by a memory system, comprising:
receiving, by a receiver coupled to the memory, a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits;
determining, by a processor coupled to the receiver and the memory, a circular shifter offset based on a write count of the first portion of the memory; and
writing, by the memory, the plurality of user bits and the plurality of ECC bits to a plurality of memory cells within the first portion of the memory and the second portion of the memory based on the circular shifter offset.

2. The method of claim 1, wherein the circular shifter offset is an integer value corresponding to a number of memory cells by which to shift the plurality of user bits and the plurality of ECC bits within the first portion of the memory and the second portion of the memory, wherein the circular shifter offset equals to the write count/K, wherein K is a predefined constant associated with the write counts.

3. The method of claim 1, wherein the write count comprises a plurality of write count bits, wherein the method further comprises performing, by the processor, balanced gray code (BGC) encoding on the plurality of write count bits of the write count after incrementing the write count and before writing the plurality of user bits and the plurality of ECC bits to the plurality of memory cells.

4. The method of claim 1, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein writing the plurality of user bits and the plurality of ECC bits to the plurality of memory cells comprises shifting a location for storing each of the plurality of user bits and the plurality of ECC bits at one of the plurality of memory cells by the circular shifter offset.

5. The method of claim 1, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein writing the plurality of user bits and the plurality of ECC bits to the plurality of memory cells comprises shifting a location for storing each of the plurality of user bits and the plurality of ECC bits at one of the plurality of memory cells by the circular shifter offset.

6. The method of claim 1, wherein the write count comprises a plurality of write count bits, and wherein the method further comprises incrementing the write count after receiving the write command.

7. The method of claim 1, further comprising computing, by the processor, the plurality of ECC bits corresponding to the plurality of user bits.

8. The method of claim 1, wherein the memory is a storage class memory, and wherein the first portion and the second portion are not contiguously stored in the memory.

9. An apparatus implemented as a memory system, comprising:
a memory storage comprising instructions; and
one or more processors in communication with the memory storage, wherein the one or more processors execute the instructions to:
receive a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits;
determine a circular shifter offset based on a write count of the first portion of the memory; and
write the plurality of user bits and the plurality of ECC bits to a plurality of memory cells within the first portion of the memory and the second portion of the memory based on the circular shifter offset.

10. The apparatus of claim 9, wherein the circular shifter offset is an integer value corresponding to a number of memory cells by which to shift the plurality of user bits and the plurality of ECC bits within the first portion of the memory and the second portion of the memory, wherein the circular shifter offset is equal to the write count/K, wherein K is a predefined constant associated with the write count.

11. The apparatus of claim 9, wherein the write count comprises a plurality of write count bits, wherein the one or more processors execute the instructions to perform balanced gray code (BGC) encoding on the plurality of write count bits of the write count after incrementing the write count and before writing the plurality of user bits and the plurality of ECC bits to the plurality of memory cells.

12. The apparatus of claim 9, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein the one or more processors execute the instructions to shift a location for storing each of the plurality of user bits and the plurality of ECC bits at one of the plurality of memory cells by the circular shifter offset.

13. The apparatus of claim 9, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein the one or more processors execute the instructions to shift a location for storing each of the plurality of user bits and the plurality of ECC bits at one of the plurality of memory cells by the circular shifter offset.

14. The apparatus of claim 9, wherein the write count comprises a plurality of write count bits, and wherein the one or more processors execute the instructions to increment the write count after receiving the write command.

15. A non-transitory medium configured to store a computer program product comprising computer executable instructions that when executed by a processor cause the processor to:
receive a write command for writing a plurality of user bits to a first portion of the memory, the write command comprising the plurality of user bits and an address of the first portion of the memory, the user bits being associated with a plurality of error-correcting code (ECC) bits stored at a second portion of the memory and used to perform error detection on the plurality of user bits;
determine a circular shifter offset based on a write count of the first portion of the memory; and
write the plurality of user bits and the plurality of ECC bits to a plurality of memory cells within the first portion of the memory and the second portion of the memory based on the circular shifter offset.

16. The non-transitory medium of claim 15, wherein the circular shifter offset is an integer value corresponding to a number of memory cells by which to shift the plurality of user bits and the plurality of ECC bits within the first portion of the memory and the second portion of the memory, wherein the circular shifter offset is equal to the write count/K, wherein K is a predefined constant associated with the write count.

17. The non-transitory medium of claim 15, wherein the write count comprises a plurality of write count bits, wherein the computer executable instructions when executed by the processor further cause the processor to perform balanced gray code (BGC) encoding on the plurality of write count bits of the write count after incrementing the write count and before writing the plurality of user bits and the plurality of ECC bits to the plurality of memory cells.

18. The non-transitory medium of claim 15, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single bit, and wherein the computer executable instructions when executed by the processor further cause the processor to shift a location for storing each of the plurality of user bits and the plurality of ECC bits at one of the plurality of memory cells by the circular shifter offset.

19. The non-transitory medium of claim 15, wherein the circular shifter offset is an integer value corresponding to a number of memory cells by which to shift the plurality of user bits and the plurality of ECC bits within the first portion of the memory and the second portion of the memory, wherein the plurality of user bits and the plurality of ECC bits are logically stored consecutively in a plurality of memory cells that are each configured to store a single nibble, wherein a nibble comprises four bits, and wherein the computer executable instructions when executed by the processor further cause the processor to shift a location for storing each of the plurality of user bits and the plurality of ECC bits at one of the plurality of memory cells by the circular shifter offset.

20. The non-transitory medium of claim 15, wherein the write count comprises a plurality of write count bits, and wherein the computer executable instructions when executed by the processor further cause the processor to:
increment the write count after receiving the write command; and
compute the plurality of ECC bits corresponding to the plurality of user bits.
